(19) United States
(12) Patent Application Publication
(10) Pub. No.: US 2011/0149647 A1
(43) Pub. Date: Jun. 23, 2011

(54) Perpendicular magnetic tunnel junctions, magnetic devices including the same and method of manufacturing a perpendicular magnetic tunnel junction

(75) Inventors: Kwang-seok Kim, Seongnam-si (KR); Taek-dong Lee, Daejeon (KR); Woo-jin Kim, Daejeon (KR); Sun-ae Seo, Hwaseong-si (KR); Kee-won Kim, Suwon-si (KR); Sun-ok Kim, Daejeon (KR)

(73) Assignees: Samsung Electronics Co., Ltd.; Korean Advanced Institute of Science and Technology

(21) Appl. No.: 12/926,442

(22) Filed: Nov. 18, 2010

(30) Foreign Application Priority Data
Dec. 21, 2009 (KR) 10-2009-0128344

(51) Int. Cl. G11C 11/14; H01L 29/82; H01L 21/02

(52) U.S. Cl. 365/171; 257/421; 438/3; 257/E29.323; 257/E21.002

(57) ABSTRACT

Provided are a perpendicular magnetic tunnel junction (MTJ), a magnetic device including the same, and a method of manufacturing the MTJ, the perpendicular MTJ includes a lower magnetic layer; a tunnelling layer on the lower magnetic layer; and an upper magnetic layer on the tunnelling layer. One of the upper and lower magnetic layers includes a free magnetic layer that exhibits perpendicular magnetic anisotropy, wherein the magnetizing direction of the free magnetic layer is changed by a spin polarization current. A polarization enhancing layer (PEL) and an exchange blocking layer (EBL) are stacked between the tunnelling layer and the free magnetic layer.

### CROSS-REFERENCE TO RELATED APPLICATIONS

This application claims priority under 35 U.S.C. §119 from Korean Patent Application No. 10-2009-0128344, filed on Dec. 21, 2009, in the Korean Intellectual Property Office, the disclosure of which is incorporated herein in its entirety by reference.

### BACKGROUND

1. Field

Example embodiments relate to magnetic devices, and more particularly, to perpendicular magnetic tunnel junctions (MTJ), magnetic devices including the same, and method of manufacturing the MTJ.

2. Description of the Related Art

A magnetic random access memory (MRAM) is a next-generation non-volatile memory that provides non-volatility, fast operation speed and/or large integration. A MRAM records data based on the tunneling magnetoresistance (TMR) phenomenon.

A general MRAM, which records data by using magnetic field, has a scalability problem.

A recently-introduced spin transfer torque MRAM (STT-MRAM), which records data by using the spin transfer torque of spin current, solves the scalability problem.

However, due to the small size of a magnetic layer of a STT-MRAM, the magnetic layer may undergo thermal fluctuation. Thermal stability of a magnetic layer is proportional to KuV/KBT. Therefore, as the magnetic anisotropy Ku and the volume V of a magnetic layer increase, the magnetic layer becomes more thermally stable.

A perpendicular magnetic anisotropic (PMA) material having a high Kᵤ is used in a large integrated MRAM having a cell size below 50 nm.

When a magnetic tunnel junction (MTJ) structure is fabricated by using a PMA material, the spin polarization value of the PMA material is smaller than that of an in-plane magnetic anisotropy (IMA) material (e.g. cobalt iron boride (CoFeB)). Therefore, it is known that it is difficult to expect a substantially large TMR in a PMA material/tunnel barrier/PMA material structure.

Therefore, a technique has been introduced for interposing a polarization enhancing layer (PEL) between a PMA material and a tunneling layer so as to obtain a substantially large TMR while utilizing the high magnetic anisotropy Kᵤ of the PMA material.

### SUMMARY

Provided are perpendicular magnetic tunnel junctions (MTJ) containing perpendicular magnetic anisotropic (PMA) materials, magnetic devices including the perpendicular MTJ and method of manufacturing the MTJ.

Additional aspects will be set forth in part in the description which follows and, in part, will be apparent from the description, or may be learned by practice of the presented example embodiments.

According to example embodiments, a perpendicular magnetic tunnel junction (MTJ) includes a lower magnetic layer, a tunnelling layer formed on the lower magnetic layer, and an upper magnetic layer formed on the tunnelling layer. One of the upper and lower magnetic layers includes a free magnetic layer, wherein the magnetizing direction of the free magnetic layer is changed by a spin polarization current and the free magnetic layer exhibits perpendicular magnetic anisotropy. A polarization enhancing layer (PEL) and an exchange blocking layer (EBL) are stacked between the tunnelling layer and the free magnetic layer. The EBL may be a non-magnetic layer.

The PEL may be an iron (Fe) layer, a Fe-based alloy layer having a body centered cubic (bcc) structure, a cobalt iron boride (CoFeB)-based amorphous alloy layer, a L21 type Heusler alloy layer or combinations thereof.

The non-magnetic amorphous layer may be a zirconium (Zr)-based amorphous alloy layer, a titanium (Ti)-based amorphous alloy layer, a palladium (Pd)-based amorphous alloy layer, an aluminium (Al)-based amorphous alloy layer or combinations thereof. The non-magnetic amorphous layer may partially have nano crystal structures.

One of the upper and lower magnetic layers not including the free magnetic layer may include another PEL that contacts the tunnelling layer.

According to example embodiments, a magnetic memory device may include a switching device, and a storage node connected to the switching device and configured for storing data. The storage node may be the perpendicular MTJ having the EBL.

According to example embodiments, a magnetic packet memory (MPM) may include a magnetic head, which includes a MTJ wherein the MTJ may be the perpendicular MTJ.

According to example embodiments, a magnetic logic device may perform logic operations by using a MTJ, wherein the MTJ may be the perpendicular MTJ.

According to example embodiments, a method of manufacturing a perpendicular MTJ includes forming a lower magnetic layer on a bottom layer, forming a tunnelling layer on the lower magnetic layer, and forming an upper magnetic layer on the tunnelling layer. One of the operations of forming the upper magnetic layer and forming the lower magnetic layer includes forming a free magnetic layer, where the magnetizing direction of the free magnetic layer is changed by a spin polarization current and the free magnetic layer exhibits perpendicular magnetic anisotropy. A polarization enhancing layer (PEL) and an exchange blocking layer (EBL) are stacked between the tunnelling layer and the free magnetic layer.

Another PEL that contacts the tunnelling layer may be formed during formation of the upper magnetic layer or the lower magnetic layer, not including the free magnetic layer.

The EBL may be a non-magnetic amorphous layer.

The PEL may be a Fe layer, a Fe-based alloy layer having a body centered cubic (bcc) structure, a CoFeB-based amorphous alloy layer, a L21 type Heusler alloy layer or combinations thereof.

### BRIEF DESCRIPTION OF THE DRAWINGS

These and/or other aspects will become apparent and more readily appreciated from the following description of example embodiments, taken in conjunction with the accompanying drawings of which:

FIG. 1 shows a graph illustrating a relationship between the exchange interaction between a polarization enhancing layer (PEL) and a graph illustrating a relationship between a perpendicular magnetic anisotropic (PMA) material and switching time;

FIG. 2 shows graphs illustrating spin torque switching characteristics according to saturation magnetization Mₛ of a PEL in a stacked structure of PMA material/PEL/tunnelling layer/PEL/PMA material;

FIG. 3 is a diagram showing a perpendicular MTJ structure according to example embodiments;

FIG. 4 is a diagram showing a second MTJ C2 according to example embodiments;

FIG. 5 is a diagram showing a magnetic random access memory (MRAM) including a perpendicular MTJ according to example embodiments;

FIG. 6 is a diagram showing a magnetic random access memory (MRAM) including a perpendicular MTJ according to example embodiments;

FIGS. 7 and 8 are diagrams showing a method of fabricating MRAM including a perpendicular MTJ according to example embodiments.

### DETAILED DESCRIPTION

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other Orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present invention is not limited to example embodiments described.

Example embodiments relate to magnetic devices, and more particularly, to perpendicular magnetic tunnel junctions (MTJ), magnetic devices including the same, and method of manufacturing the MTJ.

First, a perpendicular magnetic tunnel junction (MTJ) according to example embodiments will be described.

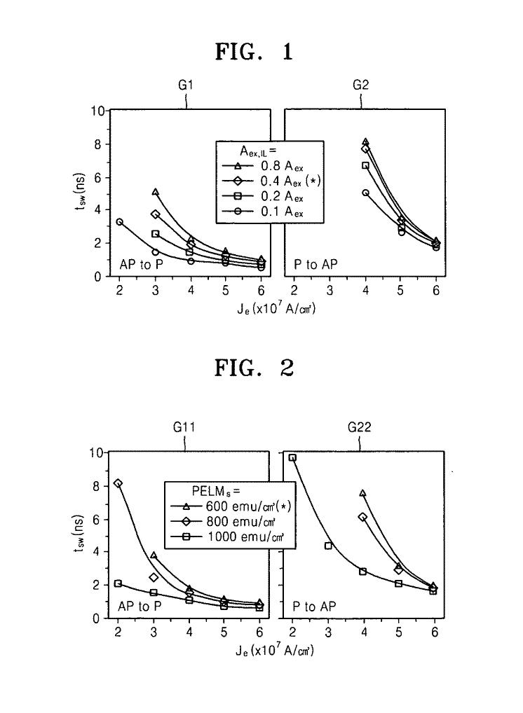

FIG. 1 shows graphs illustrating change of switching time depending on the exchange interaction between a polarization enhancing layer (PEL) and a perpendicular magnetic anisotropic (PMA) material.

In FIG. 1, the horizontal axis indicates spin current density Jₑ, and the vertical axis indicates switching time, t_{sw}. The first graph G1 shows switching time (a) when the value of the exchange interaction between a PEL of the perpendicular MTJ and the PMA material is a given value, and (b) when the magnetizing direction of a magnetic layer of a perpendicular MTJ (of which the magnetizing direction of a perpendicular MTJ is fixed) and the magnetizing direction of a free magnetic layer of a perpendicular MTJ (of which the magnetizing layer may be freely changed according to spin currents) are switched from anti-parallel to parallel. The second graph G2 shows switching time when the magnetizing directions of the magnetic layer having the fixed magnetizing direction and the free magnetic layer are switched from parallel to anti-parallel at the given exchange interaction. In the first and second graph G1 and G2, the first graph Δ indicates switching time according to spin current density when the value of the exchange interaction is 0.8 Aₑₓ, the second graph ⋄ indicates switching time according to spin current density when the value of the exchange interaction is 0.4 Aₑₓ, the third graph □ indicates switching time according to spin current density when the value of the exchange interaction is 0.2 Aₑₓ, and the fourth graph o indicates switching time according to spin current density when the value of the exchange interaction is 0.1 Aₑₓ.

Referring to FIG. 1, switching time according to spin torque increases as the strength of the exchange interaction between a PEL and a PMA material (that is, the strength of an exchange field) increases. In other words, switching due to the spin torque occurs more frequently in a perpendicular MTJ as the strength of the exchange interaction (Aₑₓ) decreases. The perpendicular MTJ refers to a MTJ including a PMA material.

FIG. 2 shows graphs illustrating spin torque switching characteristics according to saturation magnetization Mₛ of a PEL in a stacked structure of PMA material/PEL/tunnelling layer/PEL/PMA material.

In FIG. 2, the horizontal axis indicates spin current density Jₑ, and the vertical axis indicates switching time, t_{sw}.

In FIG. 2, the first graph G11 shows switching time (a) when the Mₛ value of a PEL of a perpendicular MTJ is a given value, and (b) the magnetizing direction of a magnetic layer of a perpendicular MTJ (of which the magnetizing direction is fixed) and the magnetizing direction of a free magnetic layer of a perpendicular MTJ (of which the magnetizing layer may be freely changed according to spin currents) are switched from anti-parallel to parallel. The second graph G22 shows switching time when the magnetizing directions of each of the layers are switched from parallel to anti-parallel at the given Mₛ value.

In the first and second graph G11 and G22, the first graph Δ indicates switching time according to spin current density when the Mₛ value of a PEL is 600 emu/cm³, the second graph ⋄ indicates switching time according to spin current density when the Mₛ value of a PEL is 800 emu/cm³, and the third graph □ indicates switching time according to spin current density when the Mₛ value of a PEL is 1000 emu/cm³.

Referring to FIG. 2, the spin torque switching becomes faster as the Mₛ value of the PEL increases. Therefore, a PEL having a higher Mₛ is more desirable for spin torque switching.

Referring to FIGS. 1 and 2, spin torque switching may occur more frequently in a perpendicular MTJ structure, in which a PEL having a higher Mₛ is used and exchange interaction between the PEL and a PMA material is reduced.

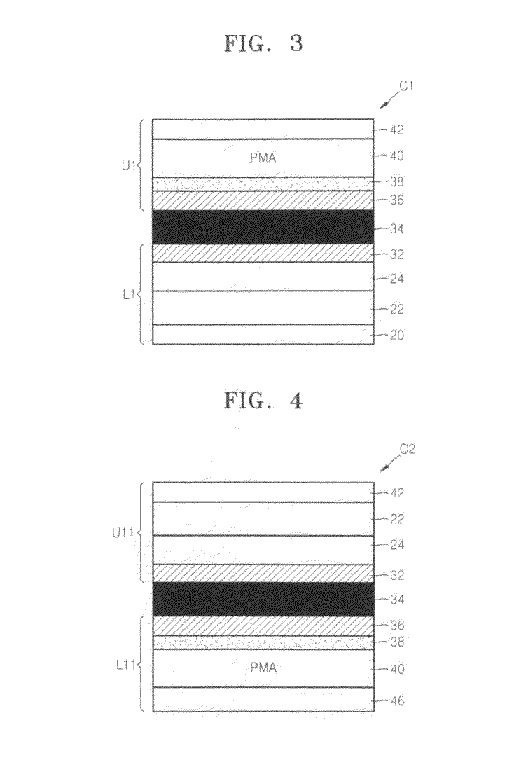

FIG. 3 is a diagram showing a perpendicular MTJ structure according to example embodiments, which is formed based on FIGS. 1 and 2.

Referring to FIG. 3, a first MTJ C1 includes a lower magnetic layer L1, a tunnelling layer 34 and an upper magnetic layer U1 which are sequentially stacked. The lower magnetic layer L1 may include a seed layer 20, a pinning layer 22, a pinned layer 24, and a first PEL 32 that are sequentially stacked.

The pinning layer 22 and the pinned layer 24 may be PMA material layers. Due to the first PEL 32, a spin current may be transmitted to the upper magnetic layer U1 without loss of spin characteristics.

The tunnelling layer 34 may, for example, be a magnesium oxide (MgO) layer or an aluminium oxide (e.g. Al₂O₃) layer. The upper magnetic layer U1 may include a second PEL 36 formed on the tunnelling layer 34. The upper magnetic layer U1 may include an exchange blocking layer (EBL) 38, a free magnetic layer 40 (which is formed of a PMA material), and a capping layer 42, which are sequentially stacked on the second PEL 36 in the order stated. The second PEL 36 may be formed of the same material as the first PEL 32. Due to the polarization enhancing feature of the second PEL 36, the spin polarization rate of the free magnetic layer 40 due to spin current may increase. As such, the tunneling magnetoresistance (TMR) of the perpendicular MTJ structure may increase. The second PEL 36 has a relatively high Mₛ. Therefore, as described above with reference to FIG. 2, switching due to the spin torque may be faster.

The EBL 38 blocks or reduces the exchange interaction between the free magnetic layer 40 and the second PEL 36. In other words, the EBL 38 blocks an exchange field between the free magnetic layer 40 and the second PEL 36 or reduces the intensity of the exchange field. Therefore, as described above with reference to FIG. 1, switching of the free magnetic layer 40 due to the spin torque may be even faster.

In the case where the exchange interaction between the free magnetic layer 40 and the second PEL 36 is blocked or reduced, the magnetization binding force of the free magnetic layer 40 with respect to the second PEL 36 disappears or is weakened. Therefore, the perpendicular magnetization state of the second PEL 36 may be inversed with a smaller spin polarization current as compared to the case in which the EBL 38 does not exist, and thus the magnetization state of the free magnetic layer 40 may be inversed. Because the magnetization state of the free magnetic layer 40 means data, spin polarization current for recording data or for spin torque switching may be reduced by introducing the EBL 38.

The capping layer 42 may be a protective layer for protecting the surfaces of the free magnetic layer 40 or the first MTJ C1.

The free magnetic layer 40 may be a perpendicular magnetic anisotropic material layer. For example, the free magnetic layer 40 may be a material layer having an ordered L10 structure (e.g., iron platinum (FePt) or cobalt platinum (CoPt)). Alternatively, the free magnetic layer 40 may be a material layer having a multilayer system, or a stacked multilayer structure, such as a Co/Pt layer, a Co/Ni layer or a Co/Pd layer. The Co/Pt layer refers to as a layer in which a Co layer and a Pt layer are sequentially stacked. The Co/Ni layer and the Co/Pd layer are also layers formed in the same manner. Alternatively, the free magnetic layer 40 may be an alloy layer containing a rare-earth material (e.g., terbium (Tb) or gadolinium (Gd)) and a transition metal (e.g., iron (Fe), cobalt (Co) or nickel (Ni)).

The PMA materials used to constitute the free magnetic layer 40 have sufficient Kᵤ values, mostly from about 10⁶ emu/cc to about 10⁸ emu/cc. The pinning layer 22 and/or the pinned layer 24 may be formed of the same material as the free magnetic layer 40.

The second PEL 36 may be a Fe layer having a high Mₛ, a Fe-based alloy layer having a body centered cubic (bcc) structure, a CoFeB-based amorphous alloy layer, an L21 type Heusler alloy layer or combinations thereof. The second PEL 36 exhibits perpendicular magnetization due to a stray field of the free magnetic layer 40 and the exchange field between the free magnetic layer 40 and the second PEL 36. Therefore, the second PEL 36 may have a sufficient thickness to be perpendicularly magnetized by the stray field or the exchange field. The thickness of the second PEL 36 may vary according to temperature and a time period for a thermal process and the anisotropic constant, the Mₛ or the thickness of a PMA material forming the free magnetic layer 40. The thickness of the second PEL 36 may be from about 0.3 nm to about 3 nm. However, example embodiments are not limited thereto.

In the case where the second PEL 36 is a Fe-based alloy layer, the second PEL 36 may be an alloy layer, which contains Fe and less than 10 weight % of vanadium (V) or molybdenum (Mo) and is capable of controlling Mₛ (e.g. an iron vanadium (FeV) layer or an iron molybdenum (FeMo) layer), or may be an iron cobalt (FeCo) layer or an iron nickel (FeNi) layer.

In the case where the second PEL 36 is a CoFeB-based amorphous alloy layer, the second PEL 36 may be, for example, a Fe rich CoFeB layer (Fe: 40% or more, B: 10-30%) or a Co rich CoFeB layer (Co: 40% or more, B: 10-30%).

In the case where the second PEL 36 is an L21 type Heusler alloy layer, the second PEL 36 may be, for example, a Co₂MnSi layer, a Co₂SiAl layer, a Co₂Cr₍₁₋ₓ₎Fe₍ₓ₎Al layer or a Co₂FeAl₍₁₋ₓ₎Si₍ₓ₎ layer.

The material layers described above as examples of the second PEL 36 may also be used as the first PEL 32. Here, the first and second PELs 32 and 36 may be either formed of the same material or different materials. For example, both of the first and second PELs 32 and 36 may be Fe-based alloy layers. Alternatively, the first PEL 32 may be a Fe-based alloy layer, and the second PEL 36 may be a CoFeB-based alloy layer.

When spin polarization current is applied to the first MTJ C1, the second PEL 36 (which has a relatively small Kᵤ and a relatively high Ms) is excited first and helps the switching of the free magnetic layer 40. Thus, the spin polarization current density J_{c} may be lowered.

Because the second PEL 36 has a relatively small Kᵤ, Mₛ may be high and the exchange field between the free magnetic layer 40 and the second PEL 36 may be small to excite the second PEL 36 by using a smaller spin polarization current. The EBL 38 blocks or reduces the exchange field between the free magnetic layer 40 and the second PEL 36. As such, the spin polarization current density for switching the free magnetic layer 40 may be further reduced.

The EBL 38 may be a non-magnetic layer having a thickness from about 0.2 nm to about 1 nm. A material layer used as the EBL 38 may vary according to the material layer used as the second PEL 36. For example, when the second PEL 36 is a CoFeB-based amorphous alloy layer, the EBL 38 may be a non-magnetic amorphous layer. Here, the EBL 38 may be a zirconium (Zr)-based amorphous alloy layer, a titanium (Ti)-based amorphous alloy layer, a palladium (Pd)-based amorphous alloy layer, an aluminium (Al)-based amorphous alloy layer or combinations thereof. The Zr-based amorphous alloy layer may be, for example, a Zr—Ti—Al-TM layer or a Zr—Al-TM layer. Here, the term ‘TM’ refers to as a transition metal. The Ti-based amorphous alloy layer may be, for example, a Ti—Ni—Sn—Be—Zr layer or a Ti—Ni—Cu layer. The Pd-based amorphous alloy layer may be, for example, a Pd—Cu—Ni—P layer or a Pd—Cu—B—Si layer. The Al-based amorphous alloy layer may be, for example, an Al—Ni—Ce layer or an Al—V—Fe layer.

In the case where the second PEL 36 is a CoFeB-based alloy layer, a non-magnetic amorphous layer (which may be used as the EBL 38) may be formed of tantalum (Ta), molybdenum (Mo), tungsten (W), niobium (Nb), vanadium (V), or alloys thereof. Such layers are overall amorphous. However, such amorphous layers may partially contain nano crystal structures.

In the case where the second PEL 36 is a Fe-based alloy layer, the EBL 38 may be a non-magnetic amorphous layer formed of chromium (Cr), copper (Cu), tantalum (Ta), molybdenum (Mo), tungsten (W), niobium (Nb), vanadium (V), or alloys thereof.

FIG. 4 is a diagram showing a second MTJ C2 according to example embodiments.

The first MTJ C1 shown in FIG. 3 has a bottom pinned layer structure in which the pinned layer 24 is located below the free magnetic layer 40, whereas the second MTJ C2 shown in FIG. 4 has a top pinned layer structure in which the pinned layer 24 is located above the free magnetic layer 40. Hereinafter, the components described above with reference to FIG. 3 will be indicated by the same reference numerals as in FIG. 3, and detailed descriptions thereof will be omitted.

Referring to FIG. 4, the second MTJ C2 includes the lower magnetic layer L11, the tunnelling layer 34 and an upper magnetic layer U11, which are sequentially stacked. The lower magnetic layer L11 includes the free magnetic layer 40, the EBL 38 and the second PEL 36, which are sequentially stacked on the seed layer 46 in the order stated. The seed layer 46 may be formed of a material suitable for growth of the free magnetic layer 40. The seed layer 46 may be either the same as or different from the seed layer 20 shown in FIG. 3. The upper magnetic layer U11 includes the pinned layer 24, the pinning layer 22 and the capping layer 42 that are sequentially stacked on the first PEL 32 in the order stated.

A magnetic device including a perpendicular MTJ according to example embodiments will be described.

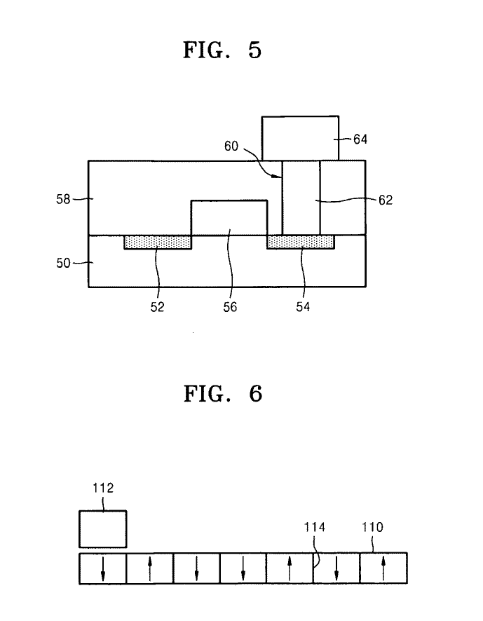

FIG. 5 is a diagram showing a magnetic random access memory (MRAM) including a perpendicular MTJ according to example embodiments.

Referring to FIG. 5, a transistor is formed on a substrate, wherein the transistors includes first and second impurity regions 52 and 54 formed in the substrate 50 and a gate 56 disposed on the substrate 50. The substrate 50 may be any of various substrates, including a p-type silicon substrate and an n-type silicon substrate, as long as a semiconductor transistor may be formed thereon. The transistor is merely an example of switching devices. Therefore, a diode may be disposed instead of the transistor. The first and second impurity regions 52 and 54 may be regions of the substrate 50 that are doped with impurities of opposite types to the substrate 50 (e.g., p-type or n-type impurities). One of the first and second impurity regions 52 and 54 may be a source region, and the other one of the first and second impurity regions 52 and 54 may be a drain region. The gate 56 is located on the substrate 50 between the first and second impurity regions 52 and 54. The gate 56 may include a gate insulation layer, a gate electrode and the like. An interlayer insulation layer 58 covering the transistor is disposed on the substrate 50. A contact hole 60 via which the second impurity region 54 is exposed is formed in the interlayer insulation layer 58, and the contact hole 60 is filled with a conductive plug 62. A perpendicular MTJ 64 covering the top surface of the conductive plug 62 is disposed on the interlayer insulation layer 58. The perpendicular MTJ 64 may be a storage node to which data is stored. The MTJ 64 may be the first MTJ C1 shown in FIG. 3 or the second MTJ C2 shown in FIG. 4. Another conductive member (not shown) may be arranged between the conductive plug 62 and the MTJ 64.

MTJs according to example embodiments may be applied not only to the magnetic memory device shown in FIG. 5, but also to other magnetic devices requiring MTJs. For example, MTJs according to example embodiments may be applied to a perpendicular magnetic recording head.

FIG. 6 is a diagram showing a magnetic random access memory (MRAM) including a perpendicular MTJ according to example embodiments.

As shown in FIG. 6, a MTJ according to example embodiments may be applied to a magnetic head 112 configured to record data to or read data from a domain wall moving recording medium 110 of a magnetic packet memory (MPM). In FIG. 6, the reference numeral 114 indicates a domain wall, and the vertical arrows indicate perpendicular magnetic polarizations of each of domains of the recording medium 110 (that is, data recorded in each of the domains). The MTJ as shown in FIG. 3 or FIG. 4 may be applied to a MTJ of a magnetic logic device for performing logic operations by using the MTJ.

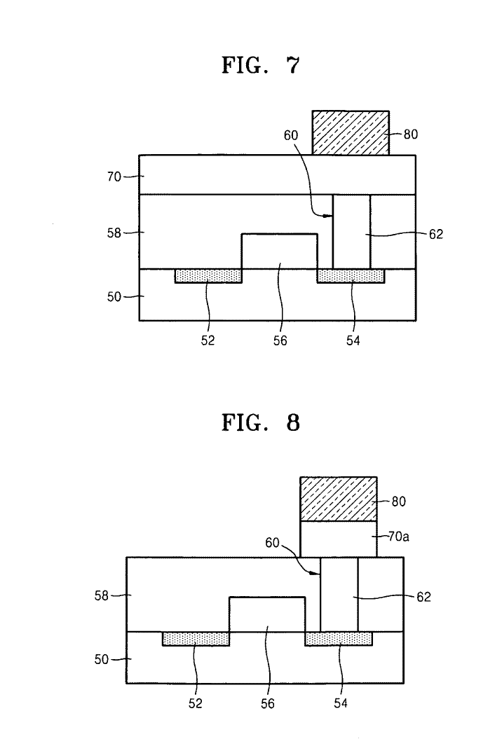

A method of manufacturing a magnetic memory device including a MTJ according to example embodiments will be described below with reference to FIGS. 7 and 8.

Referring to FIG. 7, a MTJ layer 70, which covers the top surface of the conductive plug 62, is formed on the interlayer insulation layer 58 covering the transistor shown in FIG. 5. The layer structure of the MTJ layer 70 may be same as that of the first MTJ C1 shown in FIG. 3 or the second MTJ C2 shown in FIG. 4. Therefore, detailed descriptions of the MTJ layer 70 will be omitted here.

A mask 80 is formed on a selected portion of the MTJ layer 70. The mask 80 may be a photosensitive layer pattern. The mask 80 is formed to cover the conductive plug 62. The mask 80 defines a region in which a MTJ is to be formed.

After the mask 80 is formed, the MTJ layer 70 around the mask 80 is etched. The etching operation may be performed until the interlayer insulation layer 58 is exposed. As a result, a MTJ 70a is formed on the interlayer insulation layer 58 as shown in FIG. 8. The MTJ 70a may be the first MTJ C1 shown in FIG. 3 or the second MTJ C2 shown in FIG. 4.

After the etching operation, the mask 80 is removed.

As described above, switching time may be reduced by using a MTJ according to example embodiments. In other words, the spin torque switching of a MTJ may be faster. Spin current required for inversing a state of a MTJ may be reduced. Therefore, the operating speed of a magnetic device including a MTJ according to example embodiments (e.g. a magnetic memory device) may increase, whereas current required for operating the magnetic device may decrease. A substantially large TMR may be obtained by using a PEL.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A perpendicular magnetic tunnel junction (MTJ), comprising:
a lower magnetic layer;
a tunnelling layer on the lower magnetic layer; and
an upper magnetic layer on the tunnelling layer, wherein one of the upper and lower magnetic layers includes a free magnetic layer that exhibits perpendicular magnetic anisotropy, and a magnetizing direction of the free magnetic layer is changed by a spin polarization current; and
a polarization enhancing layer (PEL) and an exchange blocking layer (EBL) stacked between the tunnelling layer and the free magnetic layer.

2. The perpendicular MTJ of claim 1, wherein the EBL has a thickness of from 0.2 nm to 1 nm.

3. The perpendicular MTJ of claim 1, wherein the PEL is one selected from the group consisting of an iron (Fe) layer, a Fe-based alloy layer having a body centered cubic (bcc) structure, a cobalt iron boride (CoFeB)-based amorphous alloy layer, a L21 type Heusler alloy layer and combinations thereof.

4. The perpendicular MTJ of claim 1, wherein the EBL is a non-magnetic layer.

5. The perpendicular MTJ of claim 4, wherein the EBL is a non-magnetic amorphous layer.

6. The perpendicular MTJ of claim 5, wherein the non-magnetic amorphous layer includes one selected from the group consisting of tantalum (Ta), molybdenum (Mo), tungsten (W), niobium (Nb), vanadium (V) and alloys thereof.

7. The perpendicular MTJ of claim 5, wherein the non-magnetic amorphous layer partially has nano crystal structures.

8. The perpendicular MTJ of claim 7, wherein the PEL is a CoFeB-based amorphous alloy layer.

9. The perpendicular MTJ of claim 5, wherein the non-magnetic amorphous layer is a layer including one selected from the group consisting of chromium (Cr), copper (Cu), tantalum (Ta), molybdenum (Mo), tungsten (W), niobium (Nb), vanadium (V) and alloys thereof.

10. The perpendicular MTJ of claim 9, wherein the PEL is a Fe-based alloy layer.

11. The perpendicular MTJ of claim 5, wherein the non-magnetic amorphous layer is one selected from the group consisting of a zirconium (Zr)-based amorphous alloy layer, a titanium (Ti)-based amorphous alloy layer, a palladium (Pd)-based amorphous alloy layer, an aluminium (Al)-based amorphous alloy layer and combinations thereof.

12. The perpendicular MTJ of claim 11, wherein the PEL is a CoFeB-based amorphous alloy layer.

13. The perpendicular MTJ of claim 11, wherein the Zr-based amorphous alloy layer is a Zr—Ti—Al-TM layer or a Zr—Al-TM layer.

14. The perpendicular MTJ of claim 11, wherein the Ti-based amorphous alloy layer is a Ti—Ni—Sn—Be—Zr layer or a Ti—Ni—Cu layer.

15. The perpendicular MTJ of claim 11, wherein the Pd-based amorphous alloy layer is a Pd—Cu—Ni—P layer or a Pd—Cu—B—Si layer.

16. The perpendicular MTJ of claim 11, wherein the Al-based amorphous alloy layer is an Al—Ni—Ce layer or an Al—V—Fe layer.

17. The perpendicular MTJ of claim 1, wherein one of the upper and lower magnetic layers not including the free magnetic layer includes another PEL that contacts the tunnelling layer.

18. The perpendicular MTJ of claim 17, wherein the PEL between the tunnelling layer and the free magnetic layer and the other PEL include either the same material or different materials.

19. A magnetic memory device, comprising:
a switching device; and
a storage node connected to the switching device, the storage node being configured to store data,
wherein the storage node is the perpendicular MTJ according to claim 1.

20. A magnetic packet memory (MPM), comprising:
a magnetic head including the perpendicular MTJ according to claim 1.

21. A magnetic logic device configured to perform logic operations using the perpendicular MTJ according to claim 1.

22. A method of manufacturing a perpendicular MTJ, the method comprising:
forming a lower magnetic layer on a bottom layer;
forming a tunnelling layer on the lower magnetic layer;
forming an upper magnetic layer on the tunnelling layer, wherein the forming of the upper magnetic layer or the forming of the lower magnetic layer includes forming a free magnetic layer that exhibits perpendicular magnetic anisotropy, a magnetizing direction of the free magnetic layer being changed by a spin polarization current, and
a polarization enhancing layer (PEL) and an exchange blocking layer (EBL) stacked between the tunnelling layer and the free magnetic layer.

23. The method of claim 22, wherein another PEL that contacts the tunnelling layer is formed during the forming of the upper magnetic layer or the lower magnetic layer, not including the free magnetic layer.

24. The method of claim 22, wherein the PEL is one selected from the group consisting of an iron (Fe) layer, a Fe-based alloy layer having a body centered cubic (bcc) structure, a cobalt iron boride (CoFeB)-based amorphous alloy layer, a L21 type Heusler alloy layer and combinations thereof.

25. The method of claim 22, wherein the EBL is a non-magnetic amorphous layer.

26. The method of claim 25, wherein the non-magnetic amorphous layer is one selected from the group consisting of a zirconium (Zr)-based amorphous alloy layer, a titanium (Ti)-based amorphous alloy layer, a palladium (Pd)-based amorphous alloy layer, an aluminium (Al)-based amorphous alloy layer and combinations thereof.

27. The method of claim 25, wherein the non-magnetic amorphous layer includes one selected from the group consisting of tantalum (Ta), molybdenum (Mo), tungsten (W), niobium (Nb), vanadium (V) and alloys thereof.

28. The method of claim 27, wherein the non-magnetic amorphous layer partially have nano crystal structures.

29. The method of claim 25, wherein the non-magnetic amorphous layer is a layer including one selected from the group consisting of chromium (Cr), copper (Cu), tantalum (Ta), molybdenum (Mo), tungsten (W), niobium (Nb), vanadium (V) and alloys thereof.
